(19) United States
(12) Patent Application Publication
(10) Pub. No.: US 2012/0155158 A1
(43) Pub. Date: Jun. 21, 2012

(54) STORAGE DEVICE AND WRITING CONTROL METHOD

(75) Inventors: Yutaka Higo, Kanagawa (JP); Masanori Hosomi, Tokyo (JP); Hiroyuki Ohmori, Kanagawa (JP); Kazuhiro Bessho, Kanagawa (JP); Kazutaka Yamane, Kanagawa (JP); Hiroyuki Uchida, Kanagawa (JP); Tetsuya Asayama, Tokyo (JP)

(73) Assignee: Sony Corporation, Tokyo (JP)

(21) Appl. No.: 13/306,451

(22) Filed: Nov. 29, 2011

(30) Foreign Application Priority Data
Dec. 20, 2010 (JP) 2010-282820

(51) Int. Cl. G11C 11/16

(52) U.S. Cl. 365/158

(57) ABSTRACT

A storage device is provided with a plurality of pairs of memory blocks, which have a storage layer which stores information and is configured to have a plurality of storage elements which store the information in the storage layer by the orientation of the magnetization of the storage layer being changed in accordance with the application of a writing voltage and so that selective application of the writing voltage is possible in accordance with input information to one storage element, and writing control sections, which store information which is to be written into each of the storage elements in a shift register, output one piece of information from the shift register, determine whether or not writing of the output information succeeds, and when writing has failed, the same information is output again, and when writing is successful, the next piece of information is output from the shift register.

### CROSS REFERENCE TO RELATED APPLICATION

The present application claims priority to Japanese Patent Application No. 2010-282820 filed on Dec. 20, 2010, the disclosure of which is incorporated herein by reference.

### BACKGROUND

The present disclosure relates to a storage device which performs information storage in a storage element using spin torque magnetization reversal.

Along with the dramatic development of various types of information devices from mobile terminals to large-capacity servers, further higher performance is demanded such as higher integration, higher speed, lower power consumption, and the like also in regard to elements such as memory and logic which configure the information devices.

In particular, the progression of semiconductor non-volatile memory is remarkable and the wide spread use of flash memory as a large-capacity file memory is progressing with the momentum being driven by hard disk drives.

On the other hand, the development of code storage and working memory is being looked into and the development of semiconductor non-volatile memory is progressing so as to replace NOR flash memory, DRAM, and the like which is currently being typically used. For example, there is FeRAM (Ferroelectric Random Access Memory), MRAM (Magnetic Random Access Memory), PCRAM (Phase Change RAM), and the like. Out of these, a portion is already in practical use.

Among these nonvolatile memory, with MRAM, high-speed rewriting and substantially unlimited rewriting (of 10¹⁵ or more times) is possible since data storage is performed using magnetization direction of a magnetic material and MRAM is already used in fields such as industrial automation, airplanes, and the like.

The development of MRAM as code storage and working memory is expected in the future due to high-speed operations and reliability.

However, MRAM has problems with lowering power consumption and increasing capacity.

This is a fundamental problem which is caused by the recording principle of MRAM, that is, a method where magnetization is reversed using a current magnetic field which is generated from wiring.

As one method of solving this problem, a recording (that is, magnetization reversal) method which does not depend on the current magnetic field is being considered, and among this, study in relation to spin torque magnetization reversal is active (for example, refer to U.S. Patent No. 5695864 and Japanese Unexamined Patent Application Publication No. 2003-17782).

The storage element in spin torque magnetization reversal is configured using a MTJ (Magnetic Tunnel Junction) which is the same as MRAM.

The MTJ is provided with a magnetized layer (referred to below as fixed magnetization layer) where magnetization is fixed in a certain direction and a magnetized layer (referred to below as storage layer) where the magnetization is not fixed, and a tunnel junction is formed by providing a tunnel insulation layer between the fixed magnetization layer and the storage layer.

Then, using the relative angle of the orientation of the magnetization of the fixed magnetization layer and the orientation of the magnetization of the storage layer, the reading out of a “0” or a “1” is performed using change in the resistance of the MTJ, that is, a so-called tunnel magnetization resistance effect.

On the other hand, since writing uses application of torque to the magnetization layer when a spin polarization element which passes through the fixed magnetization layer enters the storage layer, the orientation of the magnetization of the storage layer is reversed if there is a flow of current which is a certain threshold or more.

When writing, selection of “0” or “1” is performed by changing the polarity of the current which flows in the storage element.

The absolute value of the current for reversing the magnetization of the storage layer is 1 mA or less with a storage element of a scale of approximately 0.1 μm. Furthermore, since the current value is reduced in proportion with the volume of the storage element, scaling is possible.

Furthermore, in addition, since a word line for generating the current magnetic field for recording which is necessary in MRAM is not necessary, there is an advantage in that the cell configuration is simplified.

Below, the MRAM which uses spin torque magnetization reversal is referred to as ST-MRAM (Spin Torque—Magnetic Random Access Memory).

ST-MRAM has attracted large expectations as a non-volatile memory where low power consumption and high capacity are possible while retaining the advantages of MRAM which are high speed rewriting and infinite number of times of rewriting.

### SUMMARY

Here, in the ST-MRAM as described above, a writing current using a predetermined voltage flows in a laminate direction of the storage element for writing information in the storage element. At this time, there is a voltage of approximately 0.5V to 1V at both ends of the tunnel insulation layer of the storage element.

However, the voltage is too large to be ignored compared to a breakdown voltage of the tunnel insulation layer. That is, when repetitive writing is performed and magnetic field stress is applied to the tunnel insulation layer, there are cases where there is electrostatic discharge damage to the tunnel insulation layer. In the storage element where there is electrostatic discharge damage to the tunnel insulation layer, the resistance of the storage element itself is remarkably reduced, and furthermore, it may not be possible to read out information from the change in resistance.

In this manner, in the ST-MRAM, it is necessary that the voltage which is applied to the tunnel insulation layer during writing (“writing voltage”) is sufficiently smaller than the voltage where there is electrostatic discharge damage to the tunnel insulation layer (“breakdown voltage”). This is because, when the difference between the writing voltage and the damage voltage is small, the configuring of large capacity memory is extremely difficult due to variation in the characteristics of each storage element.

It is desirable that information is stored in a storage element while preventing damage to the storage element using the reversal of the orientation of the magnetization of a storage layer by applying a small writing voltage.

Along with this, it is desirable that high-speed writing is realized by effectively suppressing delay during writing in the storage device using an ST-RAM.

That is, it is desirable that compatibility of the realization of information storage using a small writing voltage for preventing damage to the storage element and the realization of high-speed writing is achieved.

A storage device according to an embodiment of the disclosure is configured as below.

That is, the storage device according to the embodiment of the disclosure is provided with a plurality of pairs of memory blocks and writing control sections.

That is, the memory block has a storage layer which stores information using the magnetization state of a magnetic material and a fixed magnetization layer where orientation of magnetization is fixed via a non-magnetized layer with regard to the storage layer and is configured so as to have a plurality of storage elements which store the information in the storage layer by the orientation of the magnetization of the storage layer being changed in accordance with the application of a writing voltage for flowing a writing current in a laminate direction of the storage layer and the fixed magnetization layer and so that selective application of the writing voltage is possible in accordance with input information to one storage element out of the plurality of storage elements.

In addition, the writing control section stores information which is to be written into each of the storage elements of the memory blocks in a shift register, outputs one piece of information from the shift register to the memory block, determines whether or not writing of the output information succeeds, and in a case where it is determined that writing has failed, the same information is output again with regard to the memory block, and in a case where it is determined that writing is successful, an address value for selecting the storage element which is in a writing possible state in the memory block is increased and the next piece of information is output from the shift register to the memory block.

In this manner, in the embodiment of the disclosure, since writing success determination (verification) is performed, it is possible to store information in the storage element by reversing the orientation of the magnetization of the storage layer even if there is a low writing voltage since, even when writing fails, a writing current is supplied so that the same information is output again afterward. As a result, it is possible to prevent electrostatic discharge damage of the storage element and it is possible to extend the life of the storage element.

In addition, in the embodiment of the disclosure, with the adoption of a configuration where writing control with verification in this manner (a plurality of pulse writings with verification) is possible, in the respective writing control sections which is provided for the respective memory blocks, a plurality of pieces of information which is to be written in the corresponding memory blocks is stored in the shift register and the individual writing control sections perform writing control in parallel and independently with verification with regard to the corresponding memory blocks.

An improvement in writing speed is able to be achieved by the individual writing control sections which are provided with shift registers in this manner being configured to perform writing control in parallel and independently with regard to the corresponding memory blocks.

According to the embodiment of the disclosure, it is possible to realize information storage using a small writing voltage for preventing damage of the storage element and it is possible to realize high-speed writing.

Additional features and advantages are described herein, and will be apparent from the following Detailed Description and the figures.

### BRIEF DESCRIPTION OF THE FIGURES

FIG. 1 is a diagram illustrating an internal configuration example of a memory block which is provided in a storage device according to an embodiment of the disclosure;

FIG. 2 is a cross-sectional diagram where a memory cell is modeled;

FIG. 3 is a diagram schematically illustrating an example of a writing error rate with regard to a writing voltage;

FIGS. 4A and 4B are diagrams illustrating an example of a pulse for writing;

FIG. 5 is a diagram illustrating a measurement result of writing error rate with regard to a writing voltage;

FIG. 6 is a diagram illustrating an example of a bit error rate with regard to a writing voltage;

FIG. 7 is a diagram illustrating an example of a device error rate with regard to a writing voltage;

FIG. 8 is a diagram for describing an example of a number of columns and a number of rows which are assumed in the description;

FIG. 9 is a diagram illustrating the extraction of one memory block and one writing control section;

FIG. 10 is a diagram illustrating a configuration where a plurality of pairs of memory blocks and writing control sections are provided;

FIG. 11 is a diagram schematically illustrating a writing operation using each writing control section in chronological order;

FIG. 12 is a diagram illustrating a configuration of a writing control system in the related art which performs single pulse writing;

FIG. 13 is a diagram illustrating a configuration of a writing control system which is normally considered from the configuration in the related art;

FIG. 14 is a diagram schematically illustrating a writing operation of each memory block in a writing control system which follows the configuration in the related art in chronological order; and

FIG. 15 is a diagram illustrating an overall configuration of a writing control system which includes an address control section and a transfer control section in the storage device according to an embodiment of the disclosure.

### DETAILED DESCRIPTION

Embodiments of the present application will be described below in detail with reference to the drawings.

Below, an embodiment of the disclosure will be described. Here, the description will be described in the following order.

<1. Memory Block>

[1-1. Overall Configuration of Memory Block]

[1-2. Configuration of Memory Cell]

[1-3. Writing and Read-Out Operation]

<2. Consideration of Appropriate Writing Voltage>

<3. Parallel Writing Control>

[3-1. Writing Control Section of Embodiment]

[3-2. Comparison of Configuration Normally Considered from Configuration in Related Art]

<4. Modified Example>

### 1. MEMORY BLOCK

### 1-1. Overall Configuration of Memory Block

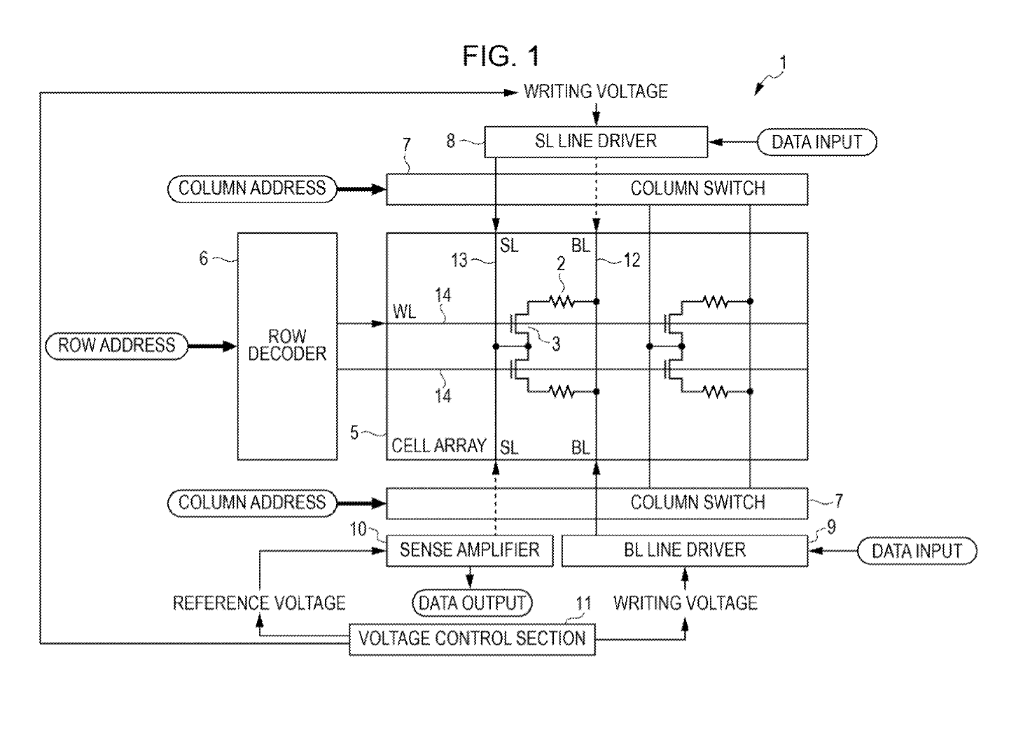

FIG. 1 is a diagram illustrating an internal configuration example of a memory block 1 which is provided in a storage device according to an embodiment of the disclosure.

In the memory block 1, storage elements 2 which store information are arranged in an array format and configure a cell array 5. Each of the storage elements 2 are connected to a pair of a bit line 12 (BL) and a source line 13 (SL) which extend up and down on the cell array 5 via a selection MOS transistor 3 and store one bit of information of “0” or “1”. On the other hand, the gate of the selection MOS transistor 3 is connected to a word line 14 (WL) which extends left and right on the cell array 5.

Here, the cell array 5 which is configured by 2 columns and 2 rows is shown in FIG. 1, but the number of columns and rows in the cell array 5 is not limited to this and may be p×q (where p is the number of columns and q is the number of rows and p≧1 and q≧1).

For example, in practice, it is possible to have a configuration of, for example, 512 rows and 512 columns. At this time, the number of word lines 14, bit lines 12 and source lines 13 are each 512.

The left end of each of the word lines 14 is connected to a row decoder 6 which is arranged to the left of the cell array 5 and the right end of each of the word lines 14 is open. The upper and lower ends of each of the source lines 13 and the bit lines 12 is connected to column switches 7 which are arranged above and below the cell array 5.

For example, in a case where the cell array 5 is configured by 512 rows and 512 columns, an address is 18 bits, but 9 higher-order bits are allocated to a row address and 9 lower-order bits are allocated to a column address. The row address is input into a row decoder 6 and the column address is input into the upper and lower column switches 7.

In addition, the memory block 1 is provided with a SL write driver 8 which adds a writing voltage to the source line 13 and a BL write driver 9 which adds a writing voltage to the bit line 12, and the SL write driver 8 and the BL write driver 9 together function as a writing section which writes information in the storage element 2.

The writing voltage for the writing section to write information into a storage block and a reference voltage which is supplied to a sense amplifier 10 are controlled using a voltage control section 11. The voltage control section 11 in this example supplies a writing current to the storage element at a writing voltage formed from one or more independent pulse lines with regard to the writing section.

In addition, the sense amplifier 10, which is connected to the source line 13 and inputs a sense voltage which is necessary for flowing the read-out current from the storage element 2, is provided in the memory block 1. One of the storage elements 2 stores information of one bit and a reference voltage of a predetermined amplitude is input into the sense amplifier 10. The sense amplifier 10 reads out information which is written into the storage element 2 by comparing the sense voltage and the reference voltage. The sense amplifier 10 of this example functions as a read-out section which reads out information from the storage element 2.

### 1-2. Configuration of Memory Cell

Next, a configuration example of a memory cell of the memory block 1 will be described.

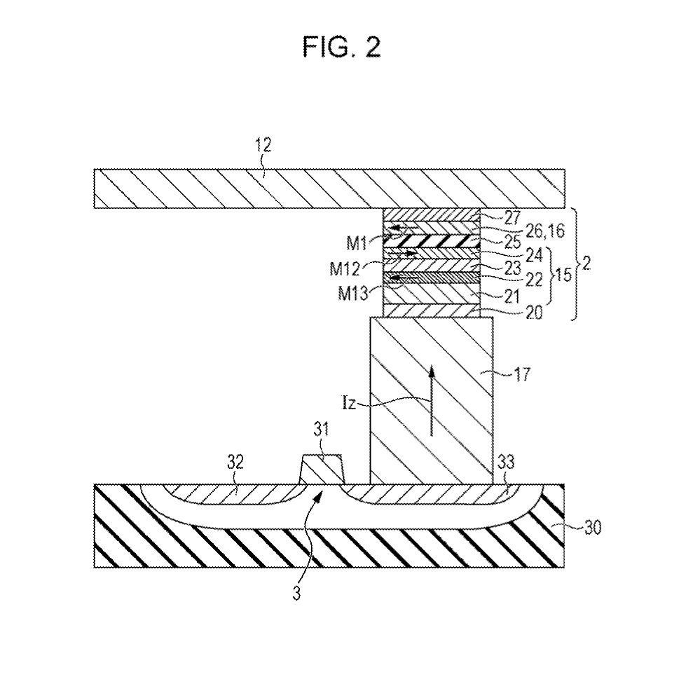

FIG. 2 is a cross-sectional diagram where a memory cell is modeled.

For confirmation, a “memory cell” indicates the structure necessary to store one bit of information.

In order to read out information stored in the memory cell, it is possible to use a diode, a MOS transistor, or the like in order to electrically select the memory cell. In the memory cell of the example shown in FIG. 2, a MOS transistor is used.

First, a configuration example of a memory cell will be described.

A ferromagnetic layer 22 and a ferromagnetic layer 24 are antiferromagnetically coupled by being arranged via a non-magnetic layer 23. Furthermore, the lower layer side of the ferromagnetic layer 22 is arranged to be in contact with an antiferromagnetic layer 21 and has magnetic anisotropy in one strong direction due to exchange interaction which operates between these layers. Then, a fixed magnetization layer 15, where the orientation of magnetization is fixed, is formed due to the layers 21, 22, 23 and 24. That is, the fixed magnetization layer 15 is formed from a plurality of the ferromagnetic layers 22 and 24 (two in this example) which are laminated via a non-magnetized layer.

A ferromagnetic layer 26 is configured so that the orientation of magnetization M1 rotates relatively easily and a storage layer (free magnetization layer) 16 is formed using the ferromagnetic layer 26. The storage layer 16 stores information using the magnetization state of the magnetic material.

Between the ferromagnetic layer 24 of the fixed magnetization layer 15 and the ferromagnetic layer 26, that is, between the fixed magnetization layer 15 and the storage layer 16, a tunnel insulation layer 25 is formed. The tunnel insulation layer 25 cuts a magnetic connection between the upper and low ferromagnetic layers 26 and 24 and serves a role of flowing a tunnel current. Due to this, a TMR (tunnel magnetoresistance effect) element is configured using the fixed magnetization layer 15 where the orientation of the magnetization of the magnetic layer is fixed, the tunnel insulation layer 25, and the storage layer 16 where it is possible to change the orientation of the magnetization.

Then, the storage element 2 which is formed from a TWR element is configured using each of the layers 21 to 26 described above, a foundation film 20, and a top coat layer 27.

It is possible for the storage element 2 to store information with regard to the storage layer 16 by changing the orientation of the magnetization of the storage layer 16 when a writing current which flows in a laminate direction is applied.

Here, it is possible to select materials of each of the layers which configures the storage element 2, for example, as follows.

As the material of the antiferromagnetic layer 21, it is possible to use, for example, PtMn.

As the material of the ferromagnetic layers 22 and 24 of the fixed magnetization layer 15, it is possible to use a ferromagnetic material such as CoFe.

As the material of the non-magnetic layer 23, it is possible to use, for example, Ru, Ta, Cr, Cu, or the like.

As the material of the tunnel insulation layer 25, it is possible to use, for example, MgO.

As the material of the ferromagnetic layer 26 of the storage layer 16, it is possible to use a ferromagnetic material such as CoFeB.

In a silicon substrate 30, a selection MOS transistor 3 is formed and a connection plug 17 is formed on one diffusion layer 33 of the selection MOS transistor 3. On the connection plug 17, the foundation film 20 of the storage element 2 is connected. The other diffusion layer 32 of the selection MOS transistor 3 is connected to the source line 13 via a connection plug which is not shown. A gate 31 of the selection MOS transistor 3 is connected to a selection signal line. The top coat layer 27 of the storage element 2 is connected to the above bit line 12.

In a steady state, orientations of a magnetization M11 of the ferromagnetic layer 22 and a magnetization M12 of the ferromagnetic layer 24 are in substantially completely opposite directions due to the strong anitferromagnetic coupling via the non-magnetic layer 23.

Normally, in the ferromagnetic layer 22 and the ferromagnetic layer 24, since the thickness layering of the saturation magnetization film has the same configuration, the leakage component of the magnetic field is small enough to be ignored.

Depending on whether the orientation of the magnetization M1 of the ferromagnetic layer 26 of the storage layer 16 and the orientation of the magnetization M12 of the ferromagnetic layer 24 of the fixed magnetization layer 15 which interpose the tunnel insulation layer 25 are in the same direction or opposite direction, the resistance value of the TMR element which is formed from the layers 24, 25 and 26 changes. In a state where the orientations of the two magnetizations M1 and M12 are in the same direction, the resistance value is low, and in a state where the orientations are in opposite directions, the resistance value is high. When the resistance value of the TMR element changes, the resistance value of the entire storage element 2 also changes. Using this, it is possible to write information into the storage element 2 and read out information from the storage element 2. For example, it is possible for information with two values (one bit) to be written in by the state where the resistance value is low being allocated with “0” information and the state where the resistance value is high being allocated with “1” information.

Here, the ferromagnetic layer 24 of the fixed magnetization layer 15 which is on the side of the storage layer 16 is referred to as a “reference layer” since it is a ferromagnetic layer which is a standard for the orientation of the magnetization M1 of the storage layer 16 and is reference when reading out stored information.

In this example, in the rewriting of information in the memory cell and the reading out of information written into the memory cell, there is a flow of a spin injection current Iz. The spin injection current Iz passes through the diffusion layer 33, the storage element 2, and the bit line 12.

On the other hand, when the polarity of the spin injection current Iz changes, it is possible to change the spin injection current Iz which flows in the storage element 2 from an upward direction to a downward direction or from a downward direction to an upward direction.

Due to this, it is possible to rewrite information in the memory cell by changing the orientation of the magnetization M1 of the storage layer 16.

### 1-3. Writing and Read-Out Operation

Next, an example of a writing operation and a read-out operation of information will be described.

In FIG. 1, the row decoder 6 sets a voltage of one of the word lines 14 out of the q word lines 14 to a power source voltage according to the row address and the selection MOS transistor 3 which is connected to the word line 14 is in an ON state. The column switch 7 on the upper side connects one of the source lines 13 out of the p source lines 13 to the SL write driver 8 according to the column address. The column switch 7 on the lower side connects one of the bit lines 12 out of the p bit lines 12 to the BL write driver 9 according to the column address.

The SL write driver 8 outputs a writing voltage when the data input is “1” and outputs GND when the data input is “0”. In contrast, the BL write driver 9 outputs a writing voltage when the data input is “0” and outputs GND when the data input is “1”. By doing this, it is possible to perform an information writing operation of “0” or “1” in the selected storage element 2 by changing the orientation of the current according to the data input.

In addition, the information read-out operation which is performed by the sense amplifier 10 is as follows.

First, the selection of the word lines 14 are the same when writing information.

The column switch 7 on the upper side connects one of the bit lines 12 out of the p bit lines 12 to the SL write driver 8 according to the column address. The column switch 7 on the lower side connects one of the source lines 13 out of the p source lines 13 to the sense amplifier 10 according to the column address. The SL write driver 8 normally outputs GND. In this manner, a constant read-out current flows in the selected storage element 2 from the sense amplifier 10.

Here, in a case where the state of the storage element 2 is “1”, that is, in a high resistance state, the sense voltage which is necessary for flowing the read-out current is set as V1. In the same manner, in a case where the state of the storage element 2 is “0”, that is, in a low resistance state, the sense voltage which is necessary for flowing the read-out current is set as V0. At this time, the amplitude relationship of the resistances is V1>V2. Therefore, a reference voltage which is smaller than V1 and larger than V2 is input into the sense amplifier 10.

The sense amplifier 10 compares the sense voltage and the reference voltage. Here, it is possible to determined that, in a case where “sense voltage>reference voltage”, the storage element 2 is in a state where “1” is stored, and in a case where “sense voltage<reference voltage”, the storage element 2 is in a state where “0” is stored. That is, it is possible to perform an information read-out operation.

### 2. CONSIDERATION OF APPROPRIATE WRITING VOLTAGE

First, an error rate will be described.

Here, an error rate when writing with regard to the storage element 2 of this example will be described.

Below, as one example of a format of magnetization when writing, it is assumed that the orientations of the magnetization M12 of the reference layer (the ferromagnetic layer 24) and the magnetization M1 of the storage layer 16 are in a state of being in the same direction in an initial state and are changed to a state of being in opposite directions due to the flow of a writing current (spin injection current Iz).

Here, even saying that the orientations of the magnetization M12 of the reference layer (the ferromagnetic layer 24) and the magnetization M1 of the storage layer 16 are in a state of being in the same direction, attention is to be paid to that the relative angle of magnetization is not completely zero degrees. The orientation of the magnetization M1 of the storage layer 16 fluctuates constantly with a distribution which is centered on zero degrees due to the effect of heat fluctuations. The power of the spin injection operates to a larger extent as the relative angle of the magnetization M12 of the reference layer (the ferromagnetic layer 24) and the magnetization M1 of the storage layer 16 becomes larger.

That is, when there is a flow of a writing current, it is possible to change to an opposite direction state with a current which is smaller when the relative angle of the magnetization M1 and M12 is larger. In contrast, it is necessary that a larger current is to be applied when the relative angle of the magnetization M1 and M12 is smaller. When there is a flow of a writing current, what orientation the magnetization M1 and M12 are facing is completely random. That is, if there are also cases where there are changes to an opposite direction state when the same writing current flows in the same element, it is possible that there are cases where the magnetizations remains in the same direction state. That the magnetizations remains in the same direction state has the meaning that the writing has failed.

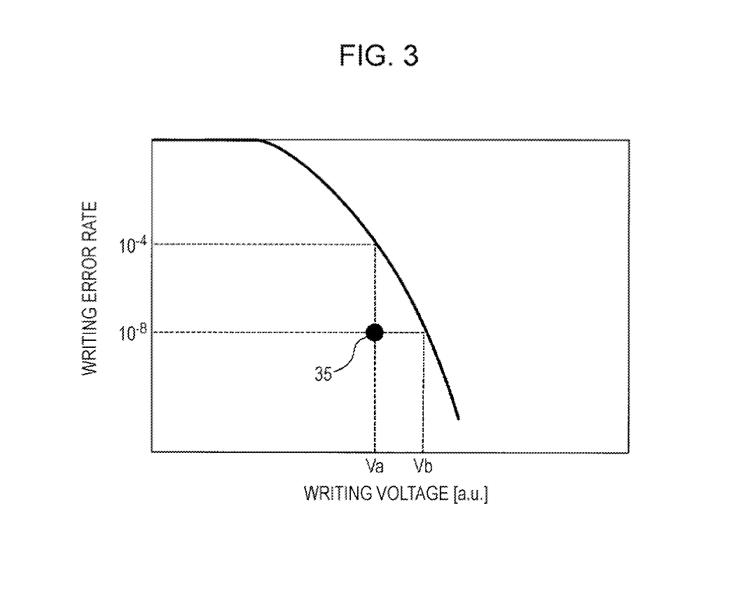

FIG. 3 schematically illustrates an example of a writing error rate with regard to a writing voltage.

The horizontal axis is the writing voltage and the vertical axis is the logarithm of the writing error rate.

That the writing error rate when a writing voltage Va is applied to the storage element 2 is 10⁻⁴ is equivalent to writing failing once in a case where writing is performed 10,000 times. As is understood by referencing FIG. 3, if the writing voltage is increased, the writing error rate steeply falls. For example, if the writing voltage increases from Va to Vb, the writing error rate falls to a frequency of once in 10⁸ times.

In this manner, it is desirable that the writing voltage is increase in order to normally perform writing. The description above is a case where the magnetization is changed from an opposite direction state to a same direction state, but the reverse case where there is a change from a same direction state to an opposite direction state is the same.

On the other hand, due to the application of the writing voltage, electric field stress operates on the tunnel insulation layer of the storage element 2. The repetitive stress eventually causes electrostatic discharge damage of the tunnel insulation layer. The electrostatic discharge damage of the tunnel insulation layer is modeled as follows.

Here, a case is considered where the writing section described above performs a repetitive voltage application with regard to the storage element 2 at a certain writing voltage.

The probability r that the storage element 2 is damaged before the writing voltage is applied x times is expressed by equation (1) below.

r=1−exp(−(x/μ)^{β)} [equation 1]

[Equation 1] expresses a Weibull distribution. β represents the form of the distribution and is normally in the range of approximately 1 to 2. μ is the average number of times which writing is possible and depends on the writing voltage.

The degree to which μ depends on the writing voltage is able to be written using a so-called power law model and is expressed by equation (2) below.

μ=x1×V^{-b} [equation 2]

Here, xl is the average number of times which writing is possible when the writing voltage is 1V and b is a parameter which determines that degree of dependency on the voltage.

Normally, when xl is in a range of approximately 10⁴ to 10¹⁰, b is in a range of approximately 40 to 60. As is understood from [equation 2], the probability of damage (=damage error rate) increases since the value of μ decreases as the writing voltage increases. As such, it is desirable to perform writing at a small writing voltage in order to lower the damage error rate of the storage element 2.

As above, it is understood that, in ST-MRAM, the writing error rate and the damage error rate have an opposite degree of dependency with regard to the writing voltage and the error rates are in a trade-off relationship. In order to realize a large capacity memory, it is necessary that there is a sufficiently large difference (=writing margin) between the writing voltage where a desired writing error rate is achieved and the writing voltage where a desired damage error rate is achieved.

Therefore, as a result of performing various studies, the present inventors found that it is possible to increase the writing margin by applying one or more pulse lines as the writing voltage.

Below, the specifics of writing using a single pulse and writing using a plurality of pulses are compared.

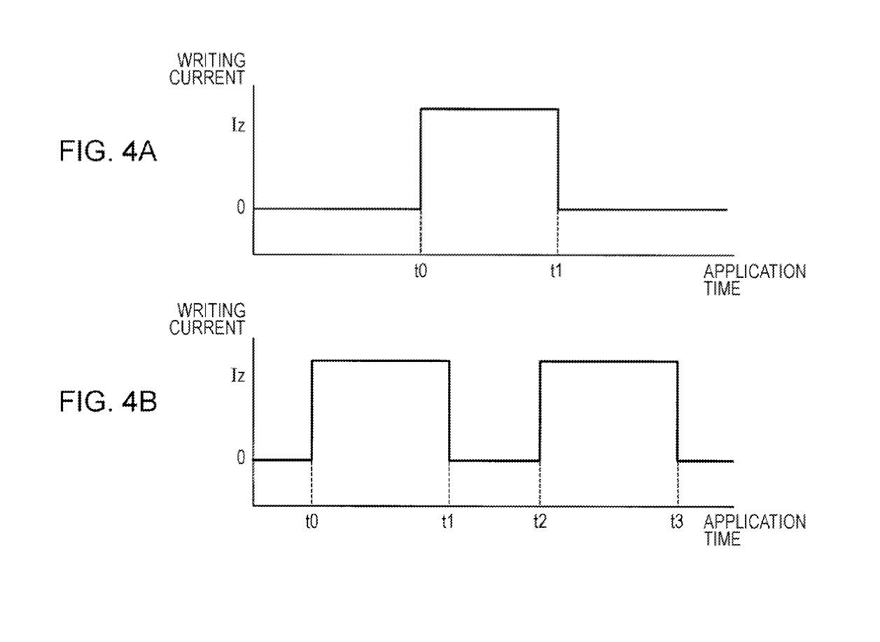

As described previously, whether writing is successful or fails due to the application of the writing voltage is random. Using FIG. 3 previously, it is shown that the writing error rate is 10⁻⁴ in a case where writing is performed using a voltage of Va and it is possible to say that writing fails once on average in 10,000 times. At this time, one pulse of the writing current flows in the storage element 2 as shown in FIG. 4A. When writing is performed using the same voltage Va in the same manner with regard to the next storage element 2, in this case also, writing fails once on average in 10,000 times.

On the other hand, it is understood that, two writings using the voltage Va. being grouped together is equivalent to writing using two continuous pulses as shown in FIG. 4B. The writing error rate of the writing using two pulses is able to be expressed as 10⁻⁴×10⁻⁴=10⁻⁸ since the information is rewritten if at least one out of the two pulses is successful at writing. That is, the writing error rate is squared.

Here, in FIG. 3 previously, the writing error rate of the writing using the two pulse line is shown by a black circle 35. The writing error rate is equivalent to a writing error rate in a case where the writing voltage is Vb which is higher than Va.

Next, in what way the damage error rate changes due to writing using two pulses in this manner will be described.

Since there is writing using two pulses, the stress which is applied to the tunnel insulation layer is double compared to the case of a single pulse. When the number of times of writing is x times, a damage error rate rl using one pulse is expressed by [equation 3] below.

r1=1−exp(−(x/μ)^{β}) [equation 3]

In addition, a damage error rate r2 using two pulses is expressed by [equation 4] below.

r2=1−exp(−(2x/μ)^{β}) [equation 4]

Since the damage error rate is a value which is extremely smaller than one (r1, r2<<1), r2≈2×r1 when performing series expansion. As a result, it is shown that the damage error rate only increases by double with regard to the writing error rate being reduced by being squared.

This difference is a reason why it is possible that the operation margin is increased by performing writing with two pulses. If the number of pulses is further increased, the effect is further increased.

Here, in the description above, the writing error rate is applied to one of the storage elements 2, but in a case of actually being used in a ST-MRAM, it is necessary that the writing error rate with regard to a plurality of storage elements 2 is used. In addition, the writing error rate is to be considered from a point that there is variation I each of the storage elements 2.

Therefore, two error rates will be defined as follows.

First, the proportion, of the storage elements 2 where writing has failed in a case where the writing is performed at a certain writing voltage with regard to a plurality of storage elements 2 is set as a writing bit error rate. The writing bit error rate is equivalent to an average value of the writing error rate of each of the storage elements 2.

On the other hand, the damage error rate is the bit error rate with regard to the plurality of storage elements 2 from the start since the original Weibull distribution is modeled with the plurality of storage elements 2 as a target.

Next, when writing is performed a necessary number of times in the ST-MRAM which is formed from the plurality of the storage element 2, the probability where the writing fails even once is the writing device error rate. The writing device error rate is an index which shows the performance of a memory device which is provided with the ST-MRAM. To what degree the writing device error rate is necessary differs due to the application which the device uses and the like, but a value in the range of 10^{-6 to} 10⁻⁴ is typically demanded.

Next, a method where the device error rate is determined from the bit error rate will be shown. Here, a case is assumed where the memory device is provided with an error correcting code function (ECC).

First, the memory capacity is set as N, the number of coding bits of the ECC (parity and data) is set as n, the number of information bits of the ECC (data) is set as k, the number of error correcting bits (number of bits which are able to be corrected) is set as s, the number of blocks (number of ECC blocks) is set as b=N/k and the number of times of writing is set as x.

At this time, the relationship between a device error rate Rd and a bit error rate Rb on the writing side is expressed by [equation 5] below.

Rd=1−(1−F[n, s, Rb]\textcircled{}(bx)) [equation 5]

Here, F[n, s, Rb] is applied by [equation 6] below using a function which shows the block error rate.

$$F ( n , s , r ) = {\sum }_{m = s + 1}^{n} ( \begin{matrix}n \\ m\end{matrix} ) {{r}^{m} ( 1 - r )}^{n - m} \qquad [ equation 6 ]$$

It is possible to derive the device error rate Rd of the damage side using the same method. However, since the number of times of writing is included in the bit error rate Rb, the device error rate Rd of the damage side is expressed by [equation 7] below.

Rd=1−(1−F[n, s, Rb]\textcircled{}(b)) [equation 7]

Here, a specific calculation example will be shown. In a case where N=76 kilobits, n=12, k=8, s=1, and x=1,000,000 times, the bit error rate Rb on the writing side which is necessary for achieving Rd of one ten thousandth is 4.4×10⁻⁹.

Next, calculation of an error rate is performed on the basis on actual measurement data in order to verify the result of writing using two or more pulses. Here, the assumed conditions for each numerical value are the same for each line of calculation.

Here, the writing error rate with regard to 128 storage elements 2 is measured in order to determine the bit error rate Rb with regard to the writing voltage.

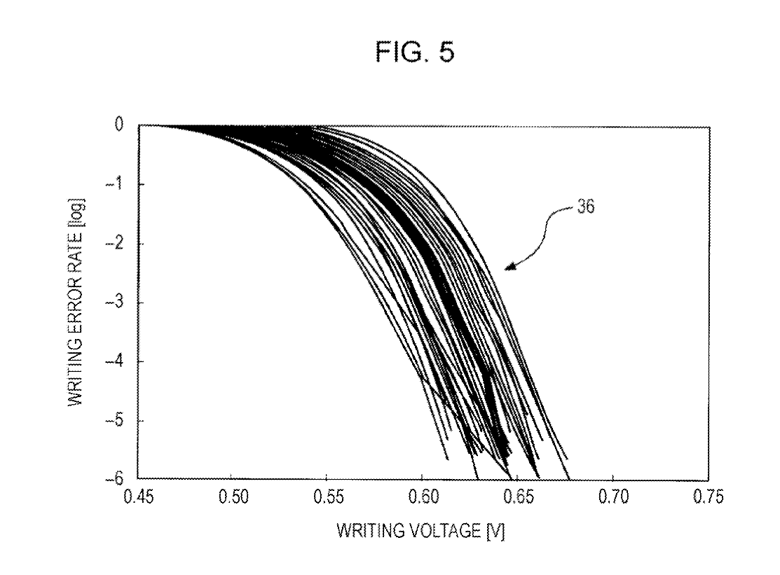

FIG. 5 illustrates a measurement result of the writing error rate with regard to the writing voltage.

One of the 36 curves shown in FIG. 5 shows the writing error rate with regard to one of the storage elements 2. The writing error rate until 10⁻⁶ is determined by performing a writing measurement which is repeated 10⁶ times in the measurement of the writing error rate. When the measurement is performed in this manner, a curve 36 is determined which is an approximation of the cumulative frequency distribution of the writing error rate for a certain writing voltage. The bit error rate Rb of the writing is determined using the numerical integration of the curve 36 in an overall bit range.

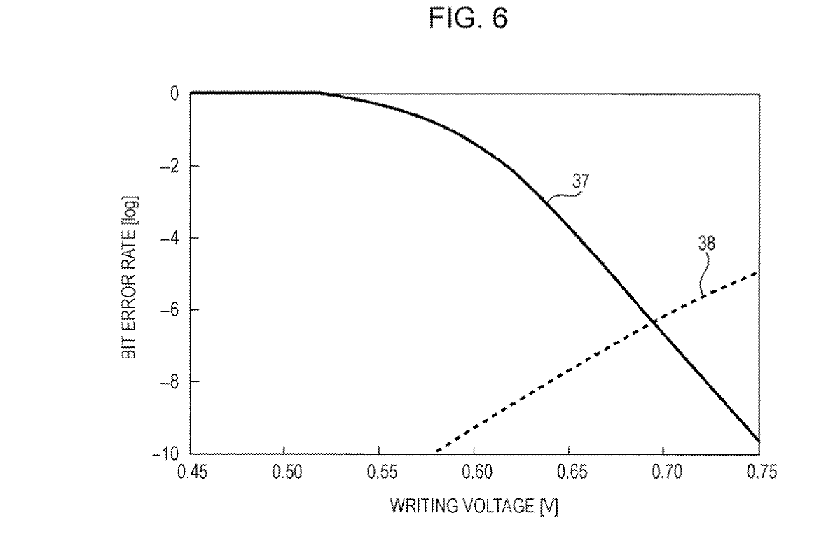

FIG. 6 illustrates an example of the bit error rate Rb with regard to the writing voltage.

However, the measurement is calculated by extrapolation with a straight line since the writing error rate which is equal to or less than 10⁻⁶ is not able to be determined.

Here, a solid line 37 represents the bit error rate Rb of the writing side and a dashed line 38 represents the bit error rate Rb of the damage side.

It is possible to determine the bit error rate Rb of the damage side by determining parameters of the Weibull distribution and the power law model using constant stress tests where a constant writing voltage is applied to the plurality of storage elements 2 and the time is measured until the storage element 2 is damaged.

As described above, there is a tendency that the bit error rate Rb of the writing side decreases as the writing voltage increases and the bit error rate Rb of the damage side increases as the writing voltage increases.

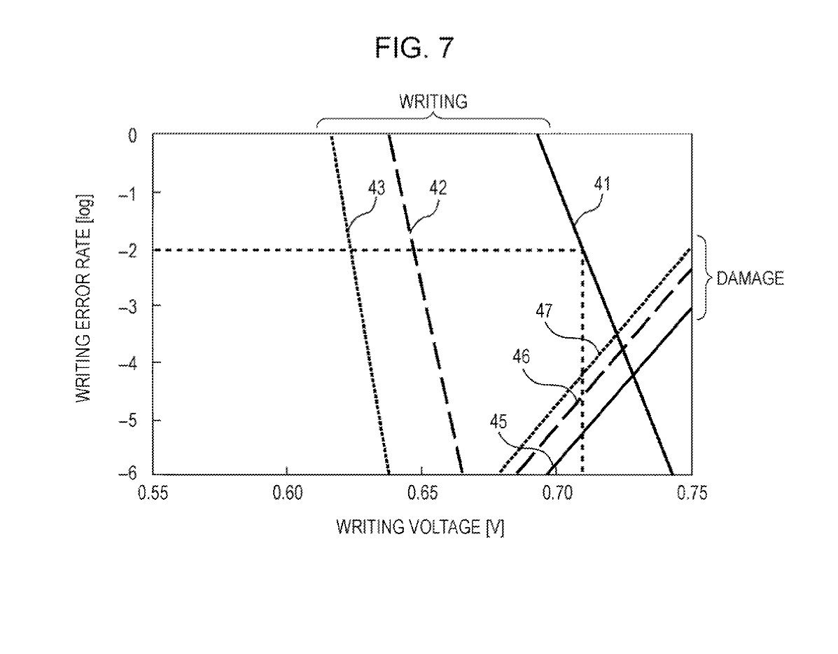

FIG. 7 illustrates an example of the device error rate Rd with regard to the writing voltage which is calculated using [equation 6] above.

Here, a line 41 shows the device error rate Rd on the writing side in a case of writing using a single pulse as in the related art. On the other hand, lines 42 and 43 show the results of the device error rates Rd on the writing side with regard to writing using two or more pulses which is performed in the ST-RAM of the example, and the line 42 shows the results of two pulses and the line 43 shows the results of three pulses.

As is understood by referencing the lines 41 to 43, the device error rate Rd on the writing side is considerably reduced compared to the writing with the single pulse due to the writing with the two pulses and the three pulses.

On the other hand, the device error rate Rd on the damage side is shown using lines 45 to 47. The line 45 is a single pulse, the line 46 is two pulses, and the line 47 is three pulses.

As shown in the diagram, according to an increase in the writing voltage, while the device error rate Rd on the writing side is considerably reduced, there is an increasing trend in the device error rate Rd on the damage side. However, as in the diagram, the extent thereof is relatively small. This is because while the device error rate Rd on the writing side is reduced by being squared or cubed, the device error rate Rd on the damage side is only being doubled or tripled.

Here, the intersection of the device error rates Rd of the writing and the damage is an operating point where the error rates on both the writing side and the damage side are reduced the most. In other words, the intersection is an optimal point where the writing side and the damage side are balanced.

At this time, in the case of a single pulse, the device error rate on the writing side when the writing voltage is approximately 0.72V is approximately 10⁻³, but in the case of two pulses, the device error rate on the writing side when the writing voltage is approximately 0.66V improves to approximately 10⁻⁵.

By performing writing in this manner using a plurality of pulses, it is possible to reduce the device error rate Rd on the writing side and on the damage side even with a low writing voltage.

The results above will be viewed using specific numerical values.

First, the writing voltage is standardized using a reference value since the writing voltage itself depends on the materials of the storage element 2, the resistance of the element, and the like. Here, in order to set the reference value of the writing voltage, a voltage which is half of the bit error rate on the writing side is set as a reference voltage VcO. In this example, the reference voltage Vc0 is set at 0.55V using FIG. 6.

In a case of evaluating the writing voltage by referencing this value, the necessary device error rate on the writing side is set as 10⁻⁵. In the writing using a single pulse in the related art, the writing voltage is 0.74V which is 1.35×Vc0. On the other hand, in the writing using a plurality of pulses in the embodiment, the writing voltage with two pulses and three pulses is respectively 0.66V which is 1.2×Vc0 and 0.63V which is 1.14×Vc0.

In this manner, it is necessary that the writing voltage which is 1.35 times the reference voltage Vc0 is applied to the storage element 2 in the writing with the single pulse in the related art.

On the other hand, it is understood that it is possible to achieve the necessary device error rate Rd by suppressing the writing voltage to 1.2 time or less of the reference voltage Vc0 due to the application of the writing with the plurality of pulses in the embodiment.

That is, according to the embodiment where writing is performed with the plurality of pulses, it is possible to reduce the writing voltage while lowering the writing error rate, the bit error rate Rb, and the device error rate Rd, and it is possible to lengthen the life time of the storage element 2 by reducing the burden applied to the storage element 2.

### 3. PARALLEl WRITING CONTROL

### 3-1. Writing Control Section of Embodiment

Here, a plurality of the memory blocks 1, which are provided with a plurality of memory cells as shown in FIG. 1, are mounted in an actual storage device. Below, a configuration (configuration of a writing control system) will be described for performing writing control in parallel with regard to the plurality of memory blocks 1 in a case where the plurality of memory blocks 1 are provided in this manner.

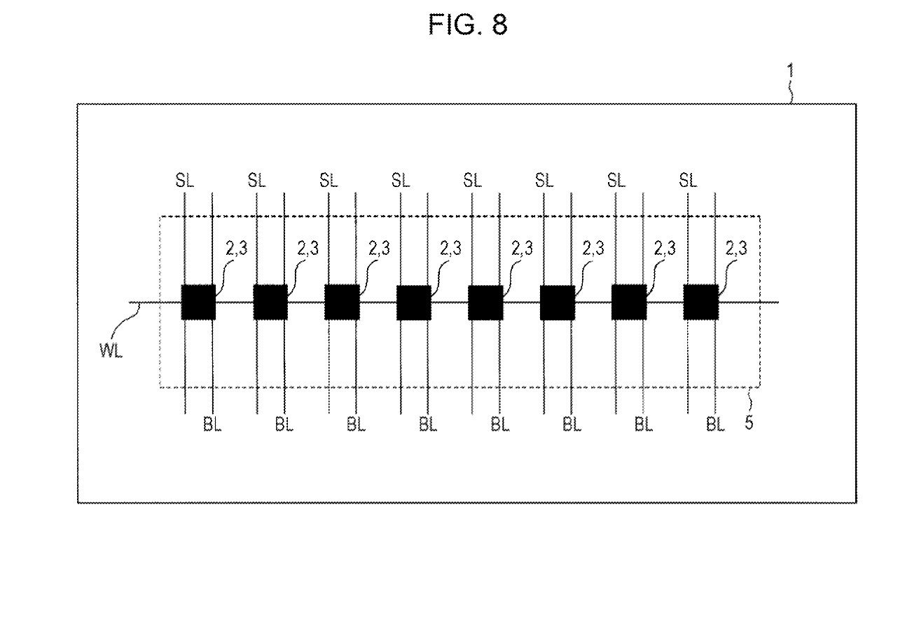

First, in performing the description below, for convenience in the diagram, the number of cells of the cell array 5 in the memory block 1 is set as eight as shown in FIG. 8.

Specifically, in the cell array 5 in this case, eight of the cell arrays which include the storage element 2 and the selection MOS transistor 3 are arranged on one row (line). That is, there is a configuration where there is eight columns and one row (p=8 and q=1).

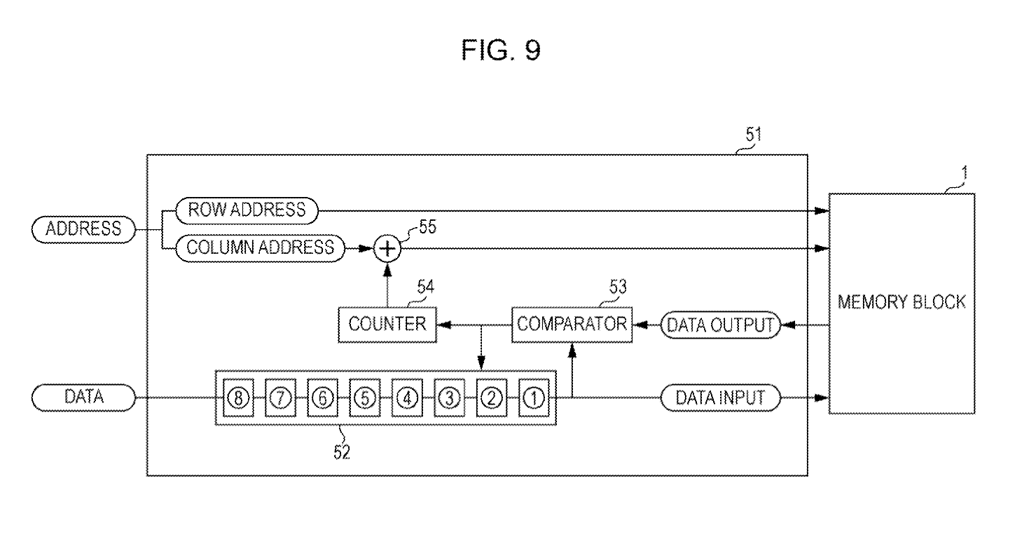

FIG. 9 is a diagram illustrating the extraction of one of the memory blocks 1 and one writing control section 51 in a configuration where writing is performed in parallel with regard to the plurality of memory blocks 1.

As shown in FIG. 9, in the writing control section 51, three input signals (the row address, the column address, and data input) are input to the memory block 1 and one output signal (data output) is output from the memory block 1.

Here, the “address” in the diagram is shown to include a row address and a column address from the convenience of diagrams hereinafter.

The writing control section 51 of the embodiment is provided with a shift register 52, a comparator 53, a counter 54, and an adding section 55 as shown in the diagram.

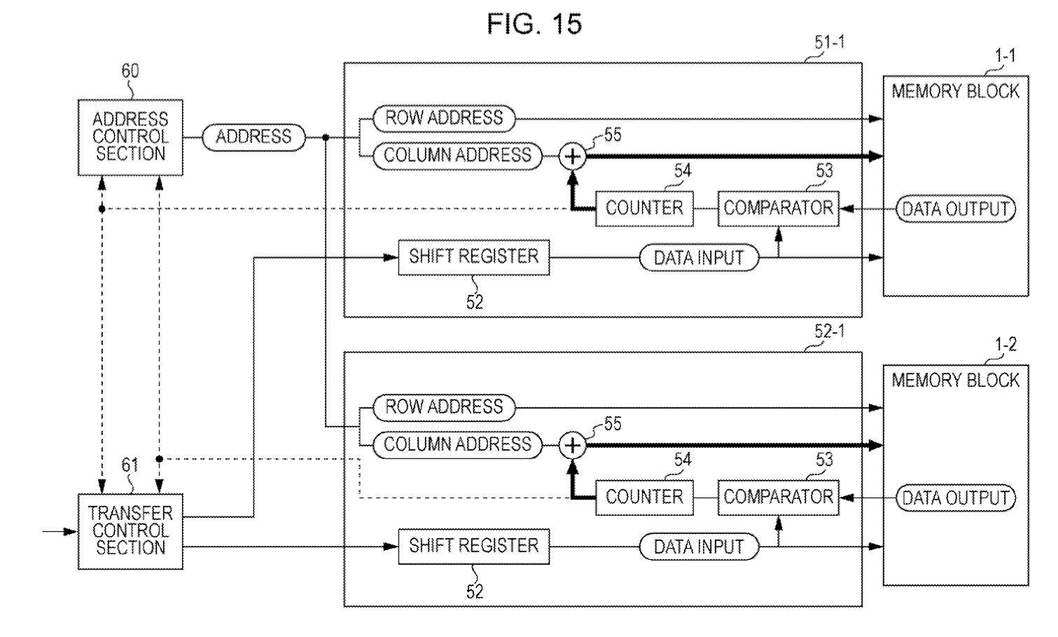

The number of bits of the shift register 52 is arbitrary, but here, the number of bits is eight bits. A data line (data line from a transfer control section 61 which will be described later: refer to FIG. 15) is connected from the outside with regard to the writing control section 51, and in the case of the shift register 52, eight bits of data (information) which is supplied from the outside is stored.

The output of the shift register 52 is supplied to the memory block 1 as the “data input” also shown in FIG. 1 and is also supplied to the comparator 53 as in the diagram.

In the comparator 53, a read-out signal is input with regard to information which is stored in the memory cell (the storage element 2) which is selected as a writing target as the “data output” from the memory block 1.

The comparator 53 compares the output of the shift register 52 described above (that is, the information bit which is supplied to the storage element 2 which is selected as the writing target) and the “data output” described above, and in a case where the two match, a signal which expresses this (referred to below as a match signal) is output to the counter 54 and the shift register 52.

On the other hand, in a case where the output of the shift register 52 and the “data output” described above do not match, a signal which expresses this (referred to below as a no-match signal) is output to the counter 54 and the shift register 52.

The comparator 53 functions as a determination section which determines whether or not information which is output from the shift register 52 as the “data input” is written into the storage element 2 which is being selected.

The counter 54 counts the number of times that the match signal is input from the comparator 53.

The adding section 55 is inserted in the address line of the column address and updates (increments) the value of the column address in accordance with the count value of the counter 54. That is, the adding section 55 operates to increment the value of the column address by one each time the match signal is output by the comparator 53.

Here, a writing sequence using the writing control section 51 which is configured as described above will be described by being split into steps.

Step 0

First, the shift register 52 stores the eight bits of data which is input via the data line from the outside. In addition, along with this, a start address (which is specified by a row address and a column address) where writing is performed via the address line is input. The counter 53 is reset to zero at a timing when the start address is supplied (a control line is not shown). Here, the zero resetting of the counter 54 to zero may be performed by an address control section 60 which will be described layer (FIG. 15).

Step 1

The data at the head of the shift register 52 (right end in the diagram) is input into the memory block 1 as the “data input”, and due to this, the writing of the data described above is performed in the storage element 2 which is specified by the start address in the memory block 1.

After the data writing, the “data output” is obtained by executing a read-out operation with regard to the storage element 2 which is specified by the start address in the memory block 1. Here, as is understood from the previous description of FIG. 1, this reading-out is executed by a read-out current flowing in the selected storage element 2 from the sense amplifier 10 using the SL write driver 8 outputting GND where one of the bit lines 12 is connected to the SL write driver 8 according to the column address using the column switch 7 on the upper side in the memory block 1 and one of the source lines 13 is connected to the sense amplifier 10 according to the column address using the column switch 7 on the lower side in the memory block 1.

The “data output” which is obtained using the read-out operation is compared to the “data input” described above in the comparator 53. The sequence progresses to step 2 in a case where the two match and the sequence progresses to step 3 in a case where the two do not match.

Step 2

In a case where the “data input” and the “data output” match, the match signal described above is output from the comparator 53 and the shift register 52 performs one bit shift in the right side in the diagram. In addition, at the same time, the value of the counter 54 is incremented by one. After the shift operation of the shift register 52 and the incrementing of the count value are executed as described above, the writing sequence continues by returning to step 1.

Due to this, it is possible to write the next data to the adjacent address.

In a case where all of the bits stored in the shift register 52 are written in, the writing sequence ends.

Step 3

Since the writing has failed, the writing sequence continues by returning to step 1 in this state.

Due to the writing sequence above, the writing is performed using the single pulse with regard to each of the storage elements 2 as long as the writing is successful.

On the other hand, in a case where the writing fails, the same data is written into the same storage element 2 (address). In other words, the writing using the plurality of pulses is executed. When writing is successful in this case also, it is possible to effectively suppress electrostatic discharge damage without excess stress being applied to the storage element since there is no writing operation beyond this.

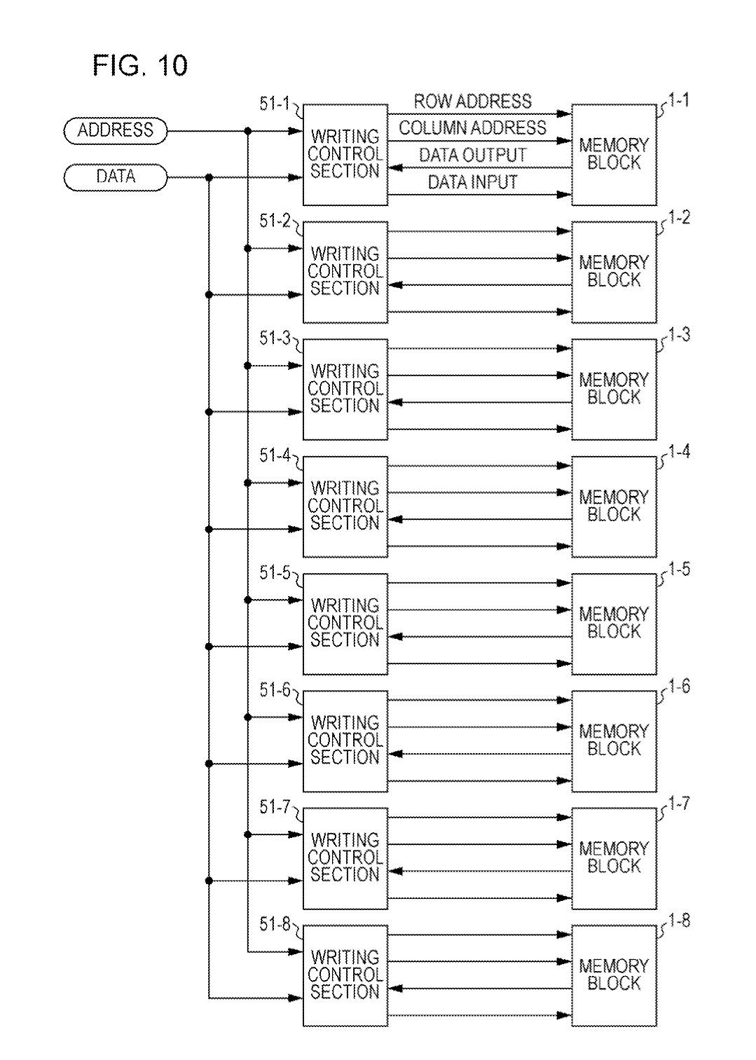

Here, in the description above, only the relationship of one pair of one of the memory blocks 1 and one of the writing control sections 51 has been described with the writing with the plurality of pulses as the main point, but a plurality of pairs of the memory blocks 1 and the writing control 51 are provided in parallel in the storage device of the embodiment which is shown in FIG. 10.

In FIG. 10, a configuration is shown as an example where eight memory blocks 1-1 to 1-8 are provided as the memory blocks 1, and corresponding to this, eight writing control sections 51-1 to 51-8 are provided as the writing control sections 51.

In FIG. 10, the writing control sections 51-1 to 51-8 receive the same “address” when the writing starts. As in understood with reference to FIG. 9, only the head address is supplied in the column address out of the “address” and the column address is incremented independently in accordance with the writing state of the memory blocks 1 which corresponds to each of the writing control sections 51.

On the other hand, with regard to the “data”, the data which corresponds respectively with regard to each of the writing control sections 51 is input.

In the case of the example, the number of data bits which is to be written into all of the eight memory blocks 1 is 8×8=64 bits. The eight bits of data which are to be written into each of the memory blocks 1 is input in the writing control sections 51 which correspond to each of the memory blocks 1.

When the writing sequence starts, the respective writing control sections 51 independently execute the writing sequence which is described above.

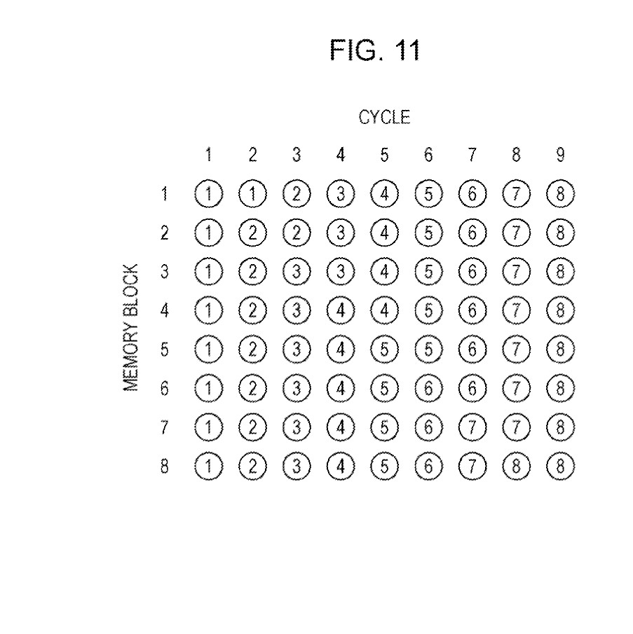

FIG. 11 schematically illustrates the writing operation using the writing control sections 51-1 to 51-8 in chronological order.

The horizontal direction represents a cycle and the vertical direction represents the respective memory blocks 1 (that is, the respective writing control sections 51).

In the example, the respective writing control sections 51 write eight pieces of data into one memory block 1 which respective corresponds thereto, but here, it is assumed that the writing fails only once in the respective memory blocks 1 and the second writing (second writing pulse) is successful. It is assumed that the remaining seven pieces of data at this time are successful with one writing.

In addition, it is assumed that there is only one of the memory blocks 1 where the writing fails in the same cycle. In order to simplify, it is assumed that the writing of the ith memory block 1 fails with the ith piece of data (cycle).

In the embodiment, each of the writing control sections 51 are provided with the shift register 52, the comparator 53, the counter 54, and the adding section 55 and operate independently. As a result, when the first writing control section 51 fails when the first piece of data is written and it is necessary that the first piece of data is written once again in the next cycle, the second to eighth writing control sections 51 are able to write in the second piece of data in the next cycle since the writing of the first piece of data was successful. Below, when the writing until the eighth piece of data is performed one after the other, the writing of all of the data is completed in nine cycles in the embodiment as shown in the diagram.

### 3-2. Comparison of Configuration Normally Considered from Configuration in Related Art

Here, the configuration of the writing control system of the embodiment, which performs the writing control independently and parallel for each of the memory blocks 1 as described above, is able to achieve a shortening of the time which is necessary to write data into all of the memory blocks 1 which are the writing targets compared to a case where a configuration is adopted which normally follows the configuration with the single pulse writing in the related art.

In the related art as described above, since it is assumed that one bit of data is stored with a single pulse, it is sufficient if the data which is to be written is supplied one bit at a time with regard to each of the memory blocks 1.

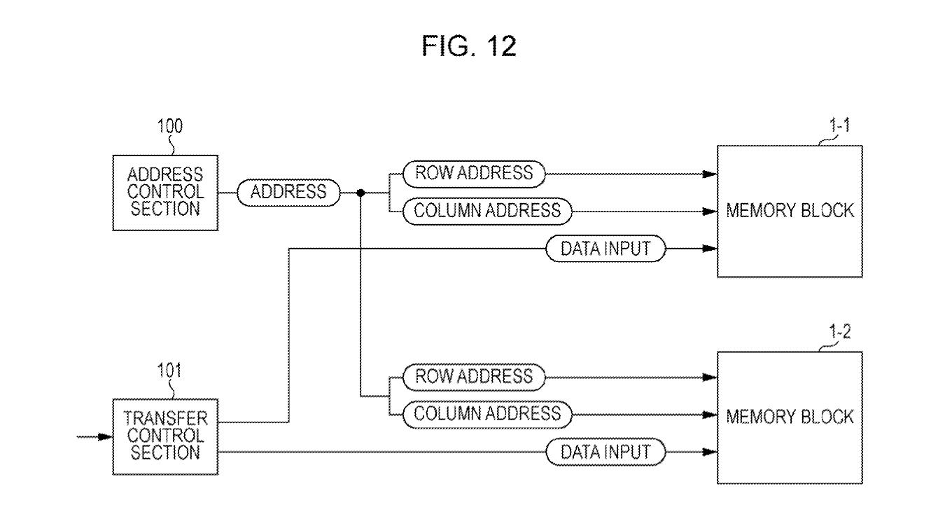

For confirmation, the configuration of the writing control system which corresponds to the single pulse writing in the related art is shown in FIG. 12.

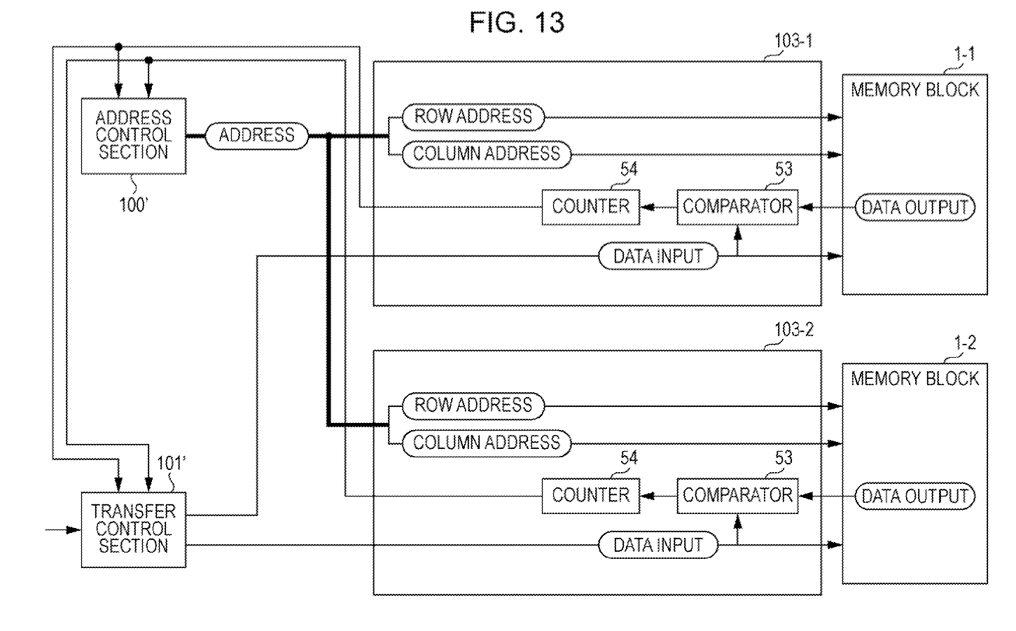

Here, for convenience in the diagram, starting from FIG. 12 and in FIGS. 13 and 15 which are described below, the number of memory blocks 1 is two.

In FIG. 12, in the configuration in the related art where the single pulse writing is performed, the data storage is executed in the memory blocks 1 by control of the “address” and control of the “data input” being performed with regard to the respective memory blocks 1 directly using an address control section 100 and a transfer control section 101.

Specifically, the address control section 100 controls the row address and the column address so that each column in a certain row is sequentially selected in each of the memory blocks 1.

In addition, the transfer control section 101 inputs data which is to be stored in the respective memory blocks 1 which is supplied from the outside, and among the data, the data which is to be stored in the memory block 1-1 and the data which is to be stored in the memory block 1-2 are transferred (output) to the memory blocks 1 which correspond thereto one bit at a time as the “data input” in the diagram.

Due to this, data is stored one bit at a time in each of the storage elements 2 of the respective memory blocks 1.

Since writing with a single pulse is assumed in the related art, a configuration is adopted where the address control section 100 and the transfer control section 101 directly perform address control and data transfer control at the same time with regard to each of the memory blocks 1.

Here, when the configuration in the related art is considered where there is a configuration where address control and data transfer control are directly performed at the same time with regard to each of the memory blocks 1, in a case where there is an attempt to realize a system where writing with the plurality of pulses with verification as in the embodiment is permitted based on the configuration in the related art, the adoption of a configuration such as FIG. 13 is normally considered as the writing Control system with regard to each of the memory blocks 1.

In FIG. 13, the writing control system in this case is provided with address control section 100′ instead of the address control section 100 which is used in the configuration in the related art in FIG. 12 and the transfer control section 101′ instead of the transfer control section 101.

In addition, in this case, a verification section 103-1 and a verification section 103-2 are provided in the diagram as a configuration for performing the verification of each one bit.

As is understood with comparison to FIG. 9 previously, each of the verification sections 103 is the same as the writing control sections 51 of the embodiment except for the shift register 52 and the adding section 55 are omitted. In this case, the output of each of the counters 54 in the verification section 103-1 and the verification section 103-2 is supplied to the address control section 100′ and the transfer control section 101′.

Here, the output of the counter 54 represents the number of bits where the verification is successful, that is, the number of bits where the writing was completed (successful). The address control section 100′ controls the updating timing of the column address value which is to be applied to each of the memory blocks 1 based on the output of each of the counters 54 in the respective verification sections 103. Specifically, both outputs from each of the counters 54 are increment by one and the column address value is sequentially updated to the next address value.

On the other hand, even with the transfer control section 101′, the transfer control of the data which is to be applied to each of the memory blocks 1 is performed based on the output of each of the counters 54 in the respective verification sections 103. Specifically, both outputs from each of the counters 54 are incremented and the output of one bit of data which is to be written into each of the memory blocks 1 is sequentially performed.

Here, since it is assumed that p=8 and q=1 in the cell array 5 in the memory block 1, the address control section 100′ in this case does not update the row address value which is applied once. Specifically, in this case, if the value of the counter 54 has an upper limit of p-1 (8-1=7 in this case), the updating of the row address is not necessary since the writing of all of the data to each of the memory blocks 1 is complete.

Here, of course, in a case where q≧2, the updating of the row address is performed. However, in this case, from the relationship where the transfer control section 101′ performs supply of data to each of the memory blocks 1 at the same time, the updating of the row address is performed at a point in time where the values of all of the counters 54 reach p-1.

In a case where the configuration in the related art such as this is followed, a configuration is normally adopted where the address control section 100′ and the transfer control section 101′ directly perform address control and data transfer control at the same time with regard to each of the memory blocks 1.

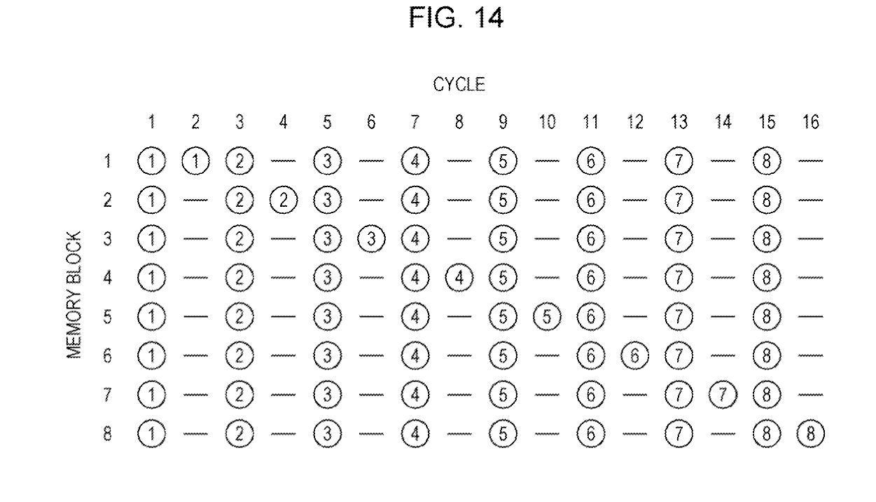

FIG. 14 schematically illustrates the writing operation of each of the memory blocks 1 in the writing control system which follows the configuration in the related art shown in FIG. 13 in chronological order.

Here, in FIG. 14, the horizontal direction in the diagram represents a cycle and the vertical direction represents the respective memory blocks 1 in the same manner as FIG. 11 previously.

In addition, with the meaning of comparison with FIG. 11, a case is shown in FIG. 14 where p=8 and q=1.

In addition, also in this case, there is only one memory block 1 where writing has failed in the same cycle, and for simplicity, it is assumed that the writing of the ith memory block 1 fails with the ith piece of data (cycle). Here, also in this case, in the storage element 2 where the writing fails, writing is successful with the second pulse.

As is understood by referencing FIG. 14, in a case of the writing control system which follows the configuration in the related art shown in FIG. 13, it is not possible to write the next piece of data until all of the data which is written in parallel has been correctly written. For example, when the first memory block 1 fails when the first piece of data is written and it is necessary that the first piece of data is written once again in the next cycle, the writing of the first piece of data was successful in the second to eighth memory blocks 1 but the second to eighth memory blocks are in a waiting state in the next cycle since the data which is to be written in is not supplied.

As shown in the diagram, the number of cycles which is necessary for the writing of all of the data of 8×8=64 bits in this case is 16 cycles.

The number of cycles which is necessary for all of the data writing using the writing control system of the embodiment with the same conditions is nine as shown in FIG. 11 previously.

As is clear from this point, the writing time is able to be significantly reduced and the speeding up of the writing operation is able to be achieved by providing the writing control section 51 of the embodiment.

Here, for confirmation, an overall configuration of the writing control system which includes the address control section and the transfer control section in the storage device of the embodiment is shown in FIG. 15.

The address control section 60 in this case indicates a head address for writing to each of the writing control sections 51 when starting writing. That is, the column address is not controlled so as to sequentially select each of the columns as with the address control section 100′ shown in FIG. 13.

In addition, the transfer control section 61 in this case inputs the data (p×q×2=8×1×2=16 bits in this case) which is to be stored in each of the memory blocks 1 and is supplied from the outside, the data (eight bits) which is to be stored in the memory block 1-1 is transferred together to the memory block 1-1, and the data (eight bits) which is to be stored in the memory block 1-2 is transferred together to the memory block 1-2. That is, the data is not transferred one bit at a time for each of the memory blocks 1 as in the transfer control section 101′ shown in FIG. 13.

Here, since it is assumed that q=1 in each of the memory blocks 1, the address control section 60 indicates the address to the writing control section 51 only when starting writing, and in addition, the transfer control section 61 also transfers the data to the writing control section 51 only when starting writing.

However, in a case where q≧2 in practice, the address control section 60 updates the row address, and in addition, the transfer control section 61 transfers the data which is to be written into a new line to the writing control section 51 each time the writing of one row (one line) is completed in all of the memory blocks 1.

To realize control which corresponds to the case where q≧2, there is a configuration where the output of the counters 54 from each of the writing control sections 51 is supplied to the address control section 60 and the transfer control section 61 as shown by the dotted line in the diagram. Then, there is a configuration where the address control section 60 updates the row address each time the value of all of the counters 54 is p-1 (8-1=7 in this case) and the transfer control section 61 transfers p bits of data which are to be newly written into each of the writing control sections 51 each time the value of all of the counters 54 is p-1.

For example, with a configuration such as this, it is possible to perform writing with a plurality of pulses with verification as the embodiment with regard to all of the storage elements 2 in the respective memory blocks 1 corresponding to the case where

### 4. MODIFIED EXAMPLE

Above, the embodiment of the disclosure has been described, but the disclosure is not limited to the specific examples described previously.

For example, in the previous description, there is an example where the fixed magnetization layer 15 is formed at a layer below the storage layer 16 in the storage element 2, but there may be a configuration where the fixed magnetization layer is formed at a layer above the storage layer 16.

In addition, in the previous description, there is an example where the fixed magnetization layer 15 is configured using the two layers of the ferromagnetic layers 22 and 24, but the number of the ferromagnetic layers which configure the fixed magnetization layer 15 is not particularly limited.

In addition, the fixed magnetization layer 15 is formed only in a layer below the storage layer 16, but it is possible for there to be a configuration where another fixed magnetization layer is formed in a layer above the storage layer 16 and the storage layer 16 is interposed by the two fixed magnetization layers.

Here, in this case, it is desirable that the orientation of the magnetization of the layer which is closest to the storage layer 16 out of the ferromagnetic layers which configure the other fixed magnetization layer is fixed to a direction which is opposite to the orientation of the magnetization of the ferromagnetic layer 24 which configures the fixed magnetization layer 15. In addition, the layer which separates the other fixed magnetization layer and the storage layer 16 may be an insulation body in the same manner as the tunnel insulation layer 25 or may be a non-magnetic metal such as Ru, Ta, Cr, Cu, or the like.

In addition, in the previous description, the pulse line which is used in writing has a rectangular shape but the pulse shape may be any shape as long as writing is able to be performed. For example, the rising or falling of the pulse or both the rising and the falling may take from a few ns to a few tens of ns of time.

In addition, in the previous description, a case is shown where verification is performed for each application of one pulse in the writing with a plurality of pulses, but it is also possible to adopt a configuration where verification is performed after the application of a plurality of pulses. In this case, it is possible to achieve a further reduction in the writing voltage.

Here, for example, in a case where there is a configuration where verification is performed for each application of a plurality of pulses in this manner, it is possible to adjust pulse widths t1-t0 and t3-t2 of each pulse line shown in FIG. 4 in accordance with the characteristics of the storage element 2 or the error rate which is demanded. There is a tendency for the writing error rate to decrease and the damage error rate to increase as the pulse width becomes longer. Typically, it is desirable that a pulse width in the range of approximately 10 ns to 300 ns is used. The pulse width of each of the pulse lines may be unified to be the same or may be set to be different widths.

It should be understood that various changes and modifications to the presently preferred embodiments described herein will be apparent to those skilled in the art. Such changes and modifications can be made without departing from the spirit and scope and without diminishing its intended advantages. It is therefore intended that such changes and modifications be covered by the appended claims.

The application is claimed as follows:

1. A storage device, comprising a plurality of pairs of memory blocks and writing control sections,
wherein the memory block has a storage layer which stores information using the magnetization state of a magnetic material and a fixed magnetization layer where orientation of magnetization is fixed via a non-magnetized layer with regard to the storage layer and is configured so as to have a plurality of storage elements which store the information in the storage layer by the orientation of the magnetization of the storage layer being changed in accordance with the application of a writing voltage for flowing a writing current in a laminate direction of the storage layer and the fixed magnetization layer and so that selective application of the writing voltage is possible in accordance with input information to one storage element out of the plurality of storage elements, and
the writing control section stores information which is to be written into each of the storage elements of the memory blocks in a shift register, outputs one piece of information from the shift register to the memory block, determines whether or not writing of the output information succeeds, and in a case where it is determined that writing has failed, the same information is output again with regard to the memory block, and in a case where it is determined that writing is successful, an address value for selecting the storage element which is in a writing possible state in the memory block is increased and the next piece of information is output from the shift register to the memory block.

2. The storage device according to claim 1, further comprising:
a transfer control section which individually applies information which is to be written into each of the storage elements in the memory blocks which form a pair with regard to the individual writing control sections; and
an address control section which indicates the head address of the writing with regard to the individual writing control sections when starting writing.

3. A writing control method of a storage device including a plurality of memory blocks, which has a storage layer which stores information using the magnetization state of a magnetic material and a fixed magnetization layer where orientation of magnetization is fixed via a non-magnetized layer with regard to the storage layer and is configured so as to have a plurality of storage elements which store the information in the storage layer by the orientation of the magnetization of the storage layer being changed in accordance with the application of a writing voltage for flowing a writing current in a laminate direction of the storage layer and the fixed magnetization layer and so that selective application of the writing voltage is possible in accordance with input information to one storage element out of the plurality of storage elements, comprising:
storing information which is to be written into each of the storage elements of the memory blocks in a shift register;
outputting one piece of information from the shift register to the memory block;
determining whether or not writing of the output information succeeds, and
outputting the same information again with regard to the memory block in a case where it is determined that writing has failed, and increasing an address value for selecting the storage element which is in a writing possible state in the memory block and outputting the next piece of information from the shift register to the memory block in a case where it is determined that writing is successful.
